(19) United States
(12) Patent Application Publication
(10) Pub. No.: US 2017/0350014 A1
(43) Pub. Date: Dec. 7, 2017

(54) PLASMA PROCESSING APPARATUS AND PLASMA PROCESSING METHOD

(71) Applicant: TOKYO ELECTRON LIMITED, Tokyo (JP)

(72) Inventors: Toshihiko IWAO, Miyagi (JP); Satoru KAWAKAMI, Miyagi (JP)

(73) Assignee: TOKYO ELECTRON LIMITED, Tokyo (JP)

(21) Appl. No.: 15/538,469

(22) PCT Filed: Dec. 14, 2015
(86) PCT No.: PCT/JP2015/084882

§ 371 Date: Jun. 21, 2017

(30) Foreign Application Priority Data
Dec. 26, 2014 (JP) 2014-266025

(51) Int. Cl. C23C 16/511; H05H 1/46; H01L 21/3065

(52) U.S. Cl. CPC C23C 16/511; H01L 21/3065; H05H 1/46

(57) ABSTRACT

This plasma processing apparatus includes a processing container that defines a plasma processing space, a holder that holds a substrate to be processed, a gas supply unit that supplies gas into the plasma processing space, an antenna that radiates microwaves to the plasma processing space, a coaxial waveguide that supplies the microwaves to the antenna, a plurality of stubs that regulate distribution of the microwaves radiated from the antenna according to an insertion amount, a measuring unit that measures density of the plasma generated in the plasma processing space by the microwaves radiated from the antenna or a parameter having a correlation with the density of the plasma along a circumferential direction of the substrate to be processed, and a controller that individually controls an insertion amount of each of the plurality of stubs based on the density of the plasma or the parameter.

### TECHNICAL FIELD

Various aspects and embodiments of the present disclosure relate to a plasma processing apparatus and a plasma processing method.

### BACKGROUND

There is a plasma processing apparatus using excitation of process gas by microwaves. This plasma processing apparatus radiates microwaves for plasma excitation into a processing container using an antenna, and dissociates gas inside the processing container so as to generate plasma. In addition, the plasma processing apparatus supplies the microwaves to the antenna by a coaxial waveguide.

However, in the plasma processing apparatus, in order to maintain uniformity of plasma density inside the processing container, it is required to maintain uniformity of distribution of the microwaves radiated from the antenna. In this regard, there has been suggested a technology which regulates the distribution of the microwaves radiated from the antenna by inserting a plurality of stubs into the coaxial waveguide, and individually controlling an insertion amount of the plurality of stubs with respect to the coaxial waveguide.

### PRIOR ART DOCUMENT

### Patent Document

Patent Document 1: Japanese Patent Publication No. 5440604

### DISCLOSURE OF THE INVENTION

### Problems to be Solved

However, the conventional technology does not even consider automatically regulating the distribution of the microwaves according to the distribution of the plasma density inside the processing container.

### Means to Solve the Problems

A plasma processing apparatus disclosed herein, in an exemplary embodiment, includes: a processing container that defines a plasma processing space; a holder that is provided inside the processing container to hold a substrate to be processed; a gas supply unit that supplies gas into the plasma processing space; an antenna that radiates microwaves for generating plasma of the gas supplied into the plasma processing space, to the plasma processing space; a coaxial waveguide that supplies the microwaves to the antenna; a plurality of stubs that are inserted into the coaxial waveguide and regulate distribution of the microwaves radiated from the antenna according to an insertion amount; a measuring unit that measures density of the plasma generated in the plasma processing space by the microwaves radiated from the antenna or a parameter having a correlation with the density of the plasma along a circumferential direction of the substrate to be processed; and a controller that individually controls an insertion amount of each of the plurality of stubs used for regulating the distribution of the microwaves, based on the density of the plasma or the parameter.

### Effect of the Invention

According to one aspect of the plasma processing apparatus described herein, it is possible to achieve an effect in which the distribution of the microwaves may be automatically regulated according to the distribution of the plasma density.

### BRIEF DESCRIPTION OF THE DRAWINGS

FIG. 1 is a sectional view schematically illustrating a principle part of a plasma processing apparatus according to an exemplary embodiment.

FIG. 2 is an enlarged sectional view schematically illustrating the vicinity of a coaxial waveguide provided in the plasma processing apparatus illustrated in FIG. 1.

FIG. 3 is a view illustrating a slot antenna plate provided in the plasma processing apparatus illustrated in FIG. 1 when viewed in the direction of arrow III in FIG. 1.

FIG. 4 is a sectional view illustrating the coaxial waveguide provided in the plasma processing apparatus illustrated in FIG. 1 which is taken along IV-IV in FIG. 2.

FIG. 5 is a view illustrating exemplary experimental results for a relationship of distribution of microwaves with an insertion amount and a material of a stub member.

FIG. 6 is a flow chart illustrating an exemplary plasma processing method using the plasma processing apparatus according to the exemplary embodiment.

FIG. 7 is an enlarged sectional view schematically illustrating the vicinity of a coaxial waveguide provided in a plasma processing apparatus according to another example embodiment.

FIG. 8 is a sectional view schematically illustrating a main part of a plasma processing apparatus according to still another exemplary embodiment.

FIG. 9 is a sectional view schematically illustrating the vicinity of the coaxial waveguide provided in the plasma processing apparatus illustrated in FIG. 8.

### DETAILED DESCRIPTION TO EXECUTE THE INVENTION

A plasma processing apparatus disclosed herein, in an exemplary embodiment, includes a processing container that defines a plasma processing space; a holder that is provided inside the processing container to hold a substrate to be processed; a gas supply unit that supplies gas into the plasma processing space; an antenna that radiates microwaves for generating plasma of the gas supplied into the plasma processing space, to the plasma processing space; a coaxial waveguide that supplies the microwaves to the antenna; a plurality of stubs that are inserted into the coaxial waveguide and regulate distribution of the microwaves radiated from the antenna according to an insertion amount; a measuring unit that measures density of the plasma generated in the plasma processing space by the microwaves radiated from the antenna or a parameter having a correlation with the density of the plasma along a circumferential direction of the substrate to be processed; and a controller that individually controls an insertion amount of each of the plurality of stubs used for regulating the distribution of the microwaves, based on the density of the plasma or the parameter.

Further, in the disclosed plasma processing apparatus, in an exemplary embodiment, the controller individually controls the insertion amount of each of the plurality of stubs so as to make the distribution of the density of the plasma or the distribution of the parameter become uniform distribution along the circumferential direction of the substrate to be processed.

Further, in the disclosed plasma processing apparatus, in an exemplary embodiment, the controller individually controls the insertion amount of each of the plurality of stubs so as to make the distribution of the density of the plasma or the distribution of the parameter become predeteimined ununiform distribution along the circumferential direction of the substrate to be processed.

Further, in the disclosed plasma processing apparatus, in an exemplary embodiment, the controller individually controls the insertion amount of each of the plurality of stubs so as to make the distribution of the density of the plasma or the distribution of the parameter become predetermined distribution obtained by reversing distribution of a film thickness, based on the distribution of the density of the plasma or the distribution of the parameter, and distribution of a film thickness on the substrate plasma-processed in the plasma processing space.

Further, in the disclosed plasma processing apparatus, in an exemplary embodiment, the parameter is at least one of a temperature of a side wall of the processing container, a temperature of the antenna, light emission intensity of the plasma processing space, and an object attached to the side wall of the processing container.

Further, in the disclosed plasma processing apparatus, in an exemplary embodiment, when a plurality of processes for plasma-processing the substrate to be processed in the plasma processing space are continuously performed, the measuring unit measures the density of the plasma or the parameter along the circumferential direction of the substrate to be processed at a timing when each of the plurality of processes is switched.

Further, in the disclosed plasma processing apparatus, in an exemplary embodiment, the coaxial waveguide includes an inner conductor and an outer conductor provided outside the inner conductor while having a gap from the inner conductor, the stubs are inserted into the gap, and a material of a portion inserted into the gap is a dielectric or a conductor.

Further, a plasma processing method disclosed herein, in an exemplary embodiment, performs a plasma processing in a plasma processing apparatus which includes: a processing container that defines a plasma processing space; a holder that is provided inside the processing container to hold a substrate to be processed; a gas supply unit that supplies gas into the plasma processing space; an antenna that radiates microwaves for generating plasma of the gas supplied into the plasma processing space, to the plasma processing space; a coaxial waveguide that supplies the microwaves to the antenna; a plurality of stubs that are inserted into the coaxial waveguide and regulate distribution of the microwaves radiated from the antenna according to an insertion amount; a measuring unit that measures density of the plasma generated in the plasma processing space by the microwaves radiated from the antenna or a parameter having a correlation with the density of the plasma along a circumferential direction of the substrate to be processed; and a controller that individually controls an insertion amount of each of the plurality of stubs used for regulating the distribution of the microwaves, based on the density of the plasma or the parameter. The plasma processing method includes: measuring density of plasma generated in the plasma processing space by the microwaves radiated from the antenna or a parameter having a correlation with the density of the plasma along a circumferential direction of the substrate to be processed; and individually controlling an insertion amount of each of the plurality of stubs used for regulating the distribution of the microwaves, based on the density of the plasma or the parameter.

Hereinafter, various exemplary embodiments will be described in detail with reference to the drawings. Further, in the respective drawings, identical or equivalent parts will be denoted by common reference numerals.

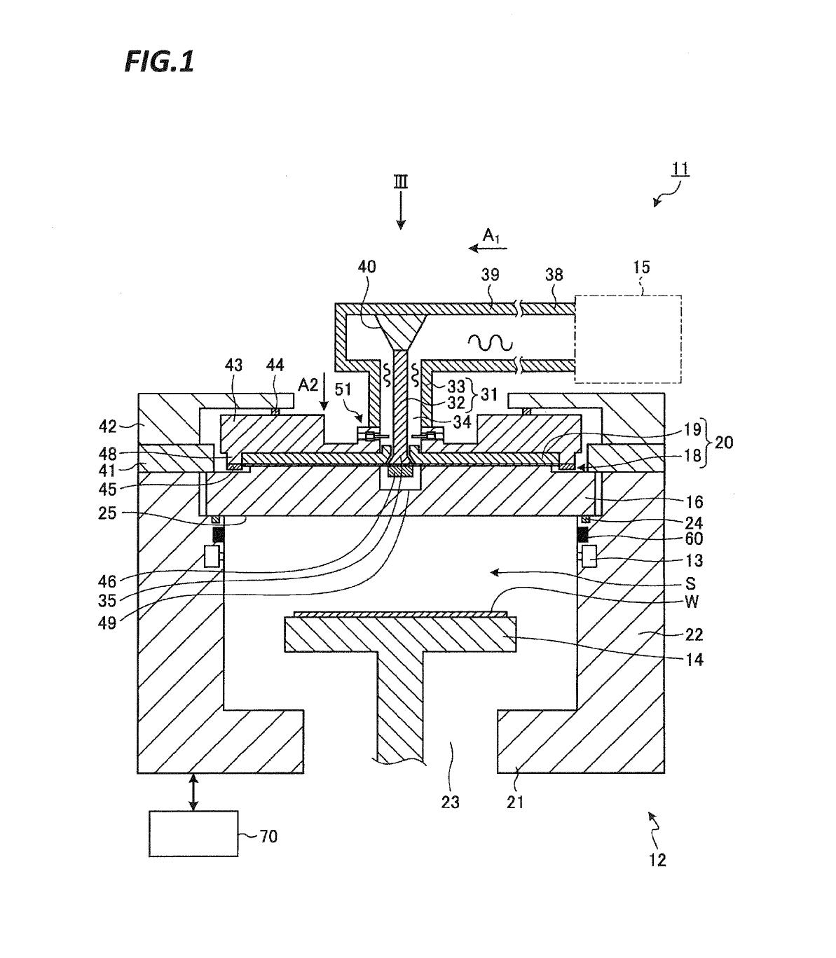

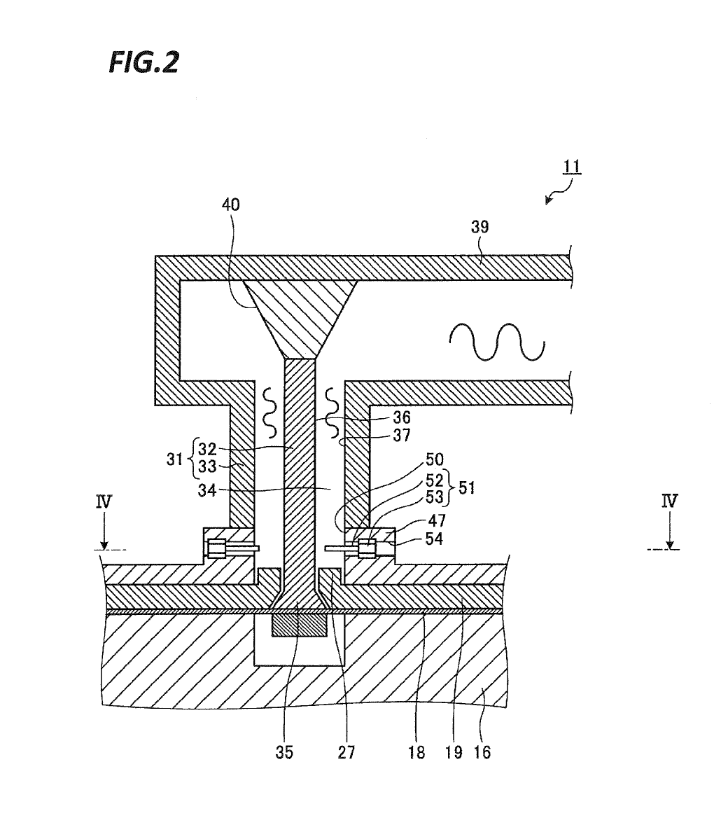

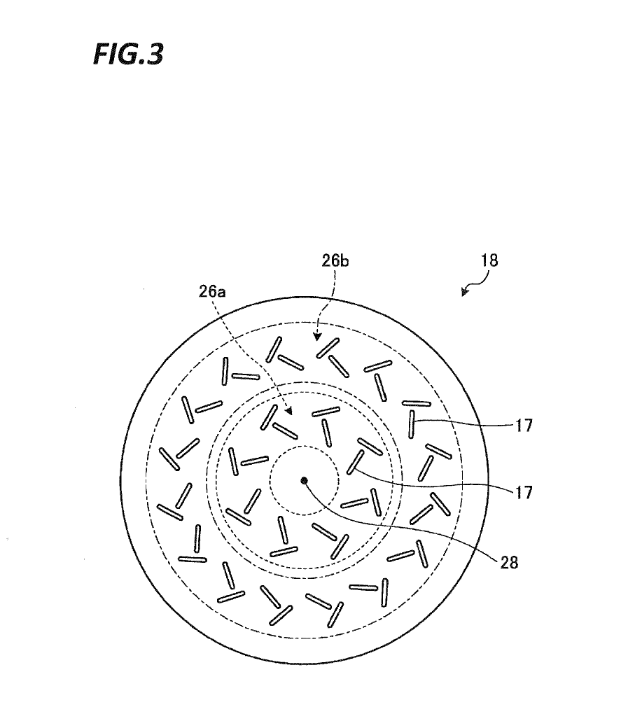

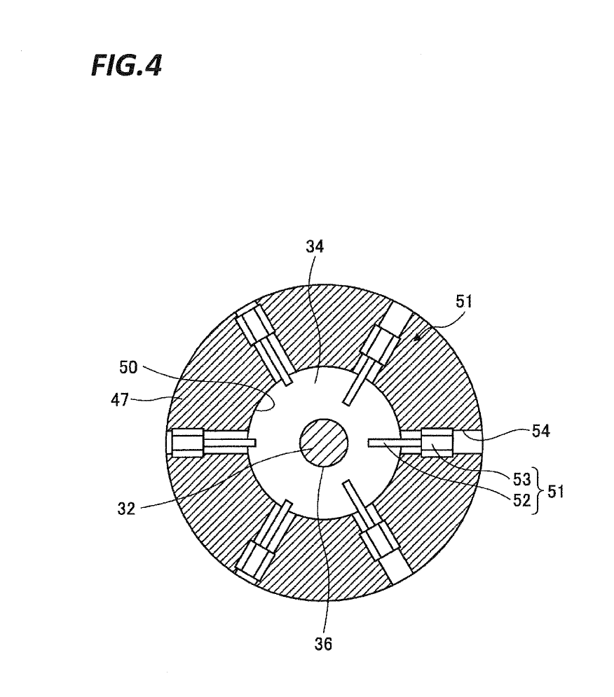

FIG. 1 is a sectional view schematically illustrating a principle part of a plasma processing apparatus according to an exemplary embodiment. FIG. 2 is an enlarged sectional view illustrating the vicinity of a coaxial waveguide provided in the plasma processing apparatus illustrated in FIG. 1. FIG. 3 is a view illustrating a slot antenna plate provided in the plasma processing apparatus illustrated in FIG. 1 when viewed in the direction of arrow III in FIG. 1. FIG. 4 is a sectional view illustrating the coaxial waveguide provided in the plasma processing apparatus illustrated in FIG. 1 which is taken along IV-IV in FIG. 2. Further, the vertical direction in the paper of each of FIGS. 1 and 2 will be regarded as the vertical direction of the apparatus. Further, in the specification of the present disclosure, the radial direction indicates the direction oriented from an inner conductor to an outer conductor which are included in a coaxial waveguide.

A plasma processing apparatus 11 illustrated in FIGS. 1 and 2 includes a processing container 12, a holding table 14, a gas supply unit 13, a microwave generator 15, a dielectric plate 16, an antenna 20, and a coaxial waveguide 31.

The processing container 12 is opened at the top side thereof, and defines a processing space S for performing a plasma processing on a target substrate W therein. The processing container 12 includes a bottom portion 21 positioned below the holding table 14, and a side wall 22 extending upwardly from the outer periphery of the bottom portion 21. The side wall 22 has a cylindrical shape. An exhaust hole 23 for exhausting gas is provided at the central side of the bottom portion 21 of the processing container 12 in the radial direction. The top side of the processing container 12 is opened, and the processing container 12 is configured to be sealed by a dielectric plate 16 disposed on the top side of the processing container 12 and an O-ring 24 as a seal member interposed between the dielectric plate 16 and the processing container 12. The surface 25 of the bottom side of the dielectric plate 16 is flat. A material of the dielectric plate 16 is a dielectric. A specific material of the dielectric plate 16 is, for example, quartz or alumina.

The gas supply unit 13 supplies gas for plasma excitation and gas for plasma processing into the processing container 12. The gas supply unit 13 is provided to be partially embedded in the side wall 22, and supplies gas into the processing space S inside the processing container 12 from the outside of the processing container 12.

The holding table 14 is disposed inside the processing container 12, and holds the target substrate W.

The microwave generator 15 is disposed outside the processing container 12, and generates microwaves for plasma excitation. Further, in an exemplary embodiment, the plasma processing apparatus 11 includes a waveguide 39 of which one end 38 is connected to the microwave generator 15, and a mode converter 40 that converts a mode of microwaves. The waveguide 39 is provided to extend horizontally, specifically, in the left-and-right direction in the paper of FIG. 1. In addition, as the waveguide 39, a waveguide having a circular or rectangular sectional surface is used.

The antenna 20 is provided on the top surface of the dielectric plate 16, and radiates microwaves for plasma generation into the processing space S through the dielectric plate 16 based on the microwaves generated by the microwave generator 15. The antenna 20 has a slot antenna plate 18 and a slow wave plate 19.

The slot antenna plate 18 is a thin plate shaped member that is disposed above the dielectric plate 16 to radiate microwaves to the dielectric plate 16. Each of the opposite surfaces of the slot antenna plate 18 in the plate thickness direction is flat. On the slot antenna plate 18, as illustrated in FIG. 3, a plurality of slot holes 17 are provided to penetrate the slot antenna plate 18 in the plate thickness direction. The slot holes 17 are configured such that two rectangular openings constitute one pair and are arranged in a substantially T shape. The provided slot holes 17 are classified into an inner circumferential side slot hole group 26a that is arranged at the inner circumferential side, and an outer circumferential side slot hole group 26b that is arranged at the outer circumferential side. The inner circumferential side slot hole group 26a includes eight slot holes 17 provided within the range surrounded by a dashed line in FIG. 3. The outer circumferential side slot hole group 26b includes sixteen slot holes 17 provided within the range surrounded by alternate long and short dashed lines in FIG. 3. In the inner circumferential side slot hole group 26a, the eight slot holes 17 are arranged annularly at equal intervals. In the outer circumferential side slot hole group 26b, the sixteen slot holes 17 are arranged annularly at equal intervals. The slot antenna plate 18 has rotational symmetry based on the center 28 in the radial direction, and has the same shape, for example, even when the slot antenna plate 18 is rotated by 45° around the center 28.

The slow wave plate 19 is disposed above the slot antenna plate 18, and propagates microwaves in the radial direction. At the center of the slow wave plate 19, an opening is provided to dispose therein an inner conductor 32 provided in the coaxial waveguide 31 to be described later. The end of the inner diameter side of the slow wave plate 19 that forms the periphery of the opening protrudes in the plate thickness direction. That is, the slow wave plate 19 has a ring shaped slow wave plate protrusion 27 that protrudes from the end of the inner diameter side in the plate thickness direction. The slow wave plate 19 is attached such that the slow wave plate protrusion 27 faces upward. A material of the slow wave plate 19 is a dielectric. A specific material of the slow wave plate 19 is, for example, quartz or alumina. The wavelength of the microwaves propagated inside the slow wave plate 19 becomes shorter than the wavelength of microwaves propagated in the air.

All the dielectric plate 16, the slot antenna plate 18, and the slow wave plate 19 have a disc shape. When manufacturing the plasma processing apparatus 11, the center of the dielectric plate 16 in the radial direction, the center of the slot antenna plate 18 in the radial direction, and the center of the slow wave plate 19 in the radial direction are made coincide with each other. Accordingly, in the microwaves propagated from the central side toward the outer diameter side, the propagation degree of the microwaves in the circumferential direction is kept the same so as to ensure the uniformity of plasma, in the circumferential direction, that is to be generated below the dielectric plate 16. In addition, here, the center 28 of the slot antenna plate 18 in the radial direction is taken as a reference.

The coaxial waveguide 31 is a waveguide that supplies microwaves to the antenna 20. The coaxial waveguide 31 includes the inner conductor 32 and the outer conductor 33. The inner conductor 32 is formed in a substantially round rod shape. One end 35 of the inner conductor 32 is connected to the center 28 of the slot antenna plate 18. The outer conductor 33 is provided at the outer diameter side of the inner conductor 32 while having a gap 34 from the inner conductor 32 in the radial direction. The outer conductor 33 is formed in a substantially cylindrical shape. That is, the coaxial waveguide 31 is configured by combining the inner conductor 32 and the outer conductor 33 such that the outer circumferential surface 36 of the inner conductor 32 and the inner circumferential surface 37 of the outer conductor 33 face each other. The coaxial waveguide 31 is provided to extend in the vertical direction in the paper of FIG. 1. The inner conductor 32 and the outer conductor 33 are manufactured as separate members. Then, the center of the inner conductor 32 in the radial direction and the center of the outer conductor 33 in the radial direction are combined to coincide with each other.

The microwaves generated by the microwave generator 15 are propagated to the antenna 20 through the waveguide 39 and the coaxial waveguide 31. As the frequency of the microwaves generated by the microwave generator 15, for example, 2.45 GHz is selected.

For example, microwaves of a TE mode generated by the microwave generator 15 are propagated inside the waveguide 39 in the paper left direction indicated by arrow A1 in FIG. 1, and converted into a TEM mode by the mode converter 40. Then, the microwaves that have been converted into the TEM mode are propagated inside the coaxial waveguide 31 in the paper downward direction indicated by arrow A2 in FIG. 1. Specifically, the microwaves are propagated in the space between the inner conductor 32 and the outer conductor 33 where the gap 34 is formed, and the space between the inner conductor 32 and a cooling plate protrusion 47. The microwaves that have been propagated through the coaxial waveguide 31 are propagated inside the slow wave plate 19 in the radial direction, and radiated to the dielectric plate 16 from the plurality of slot holes 17 provided on the slot antenna plate 18. The microwaves that have penetrated the dielectric plate 16 generate an electric field directly under the dielectric plate 16, thereby generating plasma inside the processing container 12.

Further, the plasma processing apparatus 11 includes a dielectric plate pressing ring 41 that is disposed above the upper end of the opening side of the side wall 22 to press the dielectric plate 16 from the upper side, an antenna press 42 that is disposed above the dielectric plate pressing ring 41 to press, for example, the slot antenna plate 18 from the upper side, a cooling plate 43 that is disposed above the slow wave plate 19 to cool, for example, the slow wave plate 19, an electromagnetic shielding elastic member 44 that is interposed between the antenna press 42 and the cooling plate 43 to shield an electromagnetic field inside and outside the processing container 12, an outer periphery fixing ring 45 that fixes the outer peripheral portion of the slot antenna plate 18, and a center fixing plate 46 that fixes the center of the slot antenna plate 18.

At the center of the cooling plate 43, an opening is provided to dispose therein the coaxial waveguide 31 as illustrated in FIG. 2. The end of the inner diameter side of the cooling plate 43 that forms the periphery of the opening protrudes in the plate thickness direction. That is, the cooling plate 43 has the ring shaped cooling plate protrusion 47 that protrudes from the end of the inner diameter side toward the plate thickness direction. The cooling plate 43 is attached such that the cooling plate protrusion 47 faces upward.

The cylindrical outer conductor 33 is disposed above the cooling plate protrusion 47. The upper end of the cooling plate protrusion 47 and the lower end of the outer conductor 33 are in contact with each other. In this case, the inner circumferential surface 37 of the outer conductor 33 and the inner circumferential surface 50 of the cooling plate protrusion 47 are continuous to each other, such that the distance in the radial direction between the outer circumferential surface 36 of the inner conductor 32 and the inner circumferential surface 37 of the outer conductor 33, and the distance in the radial direction between the outer circumferential surface 36 of the inner conductor 32 and the inner circumferential surface 50 of the cooling plate protrusion 47 become the same. Further, the inner circumferential surface 37 of the outer conductor 33 and the inner circumferential surface 50 of the cooling plate protrusion 47 are continuous to each other, such that the cooling plate protrusion 47 is configured as a part of the coaxial waveguide 31. In addition, the gap 34 formed between the inner conductor 32 and the outer conductor 33 is positioned above the above-described slow wave plate 27.

In addition, a slow wave plate positioning unit 48 is provided on the outer peripheral portion of the cooling plate 43 to protrude in a ring shape toward the side of the dielectric plate 16. The slow wave plate 19 is positioned in the radial direction by the slow wave plate positioning unit 48. The outer periphery fixing ring 45 fixes the slot antenna plate 18 at the position in the radial direction where the slow wave plate positioning unit 48 is provided.

In addition, an accommodating recess 49 is provided at the center of the top surface of the dielectric plate 16 in the radial direction to be recessed by reducing the plate thickness from the top surface of the dielectric plate 16 so as to accommodate the center fixing plate 46.

Further, as illustrated in FIGS. 2 and 4, the plasma processing apparatus 11 includes a plurality of stub members 51 that are extendable from the side of the outer conductor 33 toward the side of the inner conductor 32, as a changing unit that changes the distance in the radial direction between a part of the outer circumferential surface 36 of the inner conductor 32 and a facing portion that faces the part of the outer circumferential surface 36 of the inner conductor 32 in the radial direction. Further, in the present exemplary embodiment, the facing portion that faces the part of the outer circumferential surface 36 of the inner conductor 32 in the radial direction corresponds to the cooling plate protrusion 47.

Each stub member 51 includes a rod shaped portion 52 that is supported at the side of the outer conductor 33 to extend in the radial direction, and a screw portion 53 as a movement amount regulation member that regulates a movement amount of the rod shaped portion 52 in the radial direction. The screw portion 53 is provided at the end of the outer diameter side of the rod shaped portion 52.

The stub member 51 is inserted into the cooling plate protrusion 47. Specifically, the cooling plate protrusion 47 is provided with a screw hole 54 that extends straightly in the radial direction to penetrate the cooling plate protrusion 47, and the screw hole 54 and the screw portion 53 are screw-connected to each other such that the stub member 51 is inserted into the cooling plate protrusion 47. That is, the stub member 51 is supported at the side of the outer conductor 33 by the screw portion 53 screw-connected to the screw hole 54 provided in the cooling plate protrusion 47.

By rotating the screw portion 53, the entire stub member 51 including the rod shaped portion 52 may be moved in the radial direction. In FIG. 2, the stub member 51 is movable in the left-and-right direction of the paper. In addition, the movement amount is regulated by a rotation amount of the screw portion 53.

A plurality of stub members 51 (six in FIG. 4) are provided in the cooling plate protrusion 47 around the inner conductor 32 to be substantially equally arranged in the circumferential direction. For example, when six stub members 51 are provided, the six stub members 51 are arranged to be spaced apart from each other such that an angle between adjacent stub members in the circumferential direction is 60°.

Each of the plurality of stub members 51 may independently move in the radial direction. The movement of each of the stub members 51 is performed using a driving mechanism (not illustrated). By rotating the screw portion 53 of each of the stub members 51, it is possible to individually control the insertion amount of each of the stub members 51 (the rod shaped portions 52) into the gap 34 provided between the outer circumferential surface 36 of the inner conductor 32 and the inner circumferential surface 50 of the cooling plate protrusion 47. The plurality of stub members 51 regulate the distribution of the microwaves radiated from the antenna 20 according to the individually controlled insertion amount. Further, the control of the insertion amount of each of the stub members 51 is performed by a controller 70 to be described later.

A material of at least the portion of each stub member 51 that is inserted into the gap 34 is a dielectric or a conductor. The dielectric is, for example, quartz or alumina. The conductor is, for example, metal.

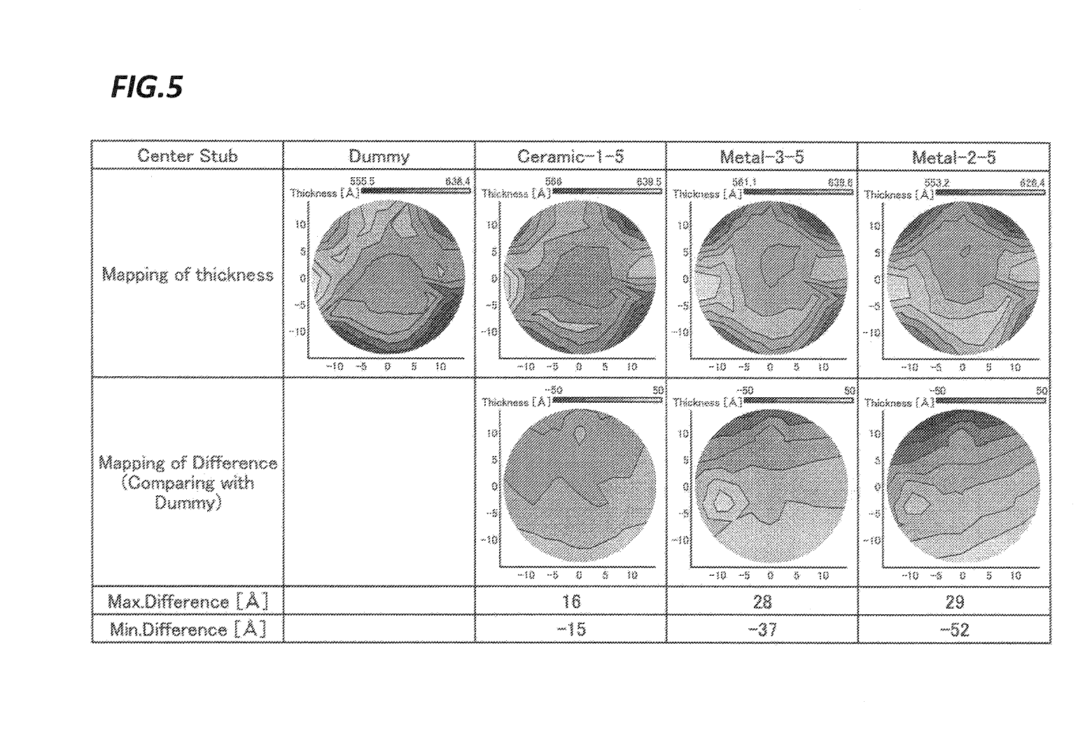

FIG. 5 is a view illustrating exemplary experimental results for a relationship of the distribution of the microwaves with the insertion amount and the material of the stub member in an exemplary embodiment. In FIG. 5, “Center Stub” represents the respective experimental results. In the experimental results, “Dummy” represents an experimental result for a case where no stub member 51 is provided. Further, “Ceramic-1-5” represents experimental results for a case where the material of the stub member 51 is a dielectric, the distance between the tip end of the rod shaped portion 52 of the stub member 51 and the inner conductor 32 (hereinafter, referred to as a “stub gap”) is 1 mm, and an insertion direction of the stub member 51 with respect to a reference direction is the direction of 5 o'clock. Further, “Metal-3-5” represents experimental results for a case where the material of the stub member 51 is a conductor, the stub gap is 3 mm, and the insertion direction of the stub member 51 with respect to the reference direction is the direction of 5 o'clock. Further, “Metal-2-5” represents experimental results for a case where the material of the stub member 51 is a conductor, the stub gap is 2 mm, and the insertion direction of the stub member 51 with respect to the reference direction is the direction of 5 o'clock.

In addition, in FIG. 5, “Mapping of thickness” represents distribution of a film thickness on the target substrate W, as an experimental result. Further, in FIG. 5, “Mapping of Difference (Comparing with Dummy)” represents distribution of a film thickness difference based on the film thickness on the target substrate W when no stub member 51 is provided. Further, in FIG. 5, “Max. Difference [A]” represents a maximum value of the film thickness difference, and “Min. Difference [A]” represents a minimum value of the film thickness difference. Further, the example of FIG. 5 represents that, as an absolute value of the maximum value of the film thickness difference and an absolute value of the minimum value of the film thickness difference are large, the regulation range of the distribution of the microwaves (the distribution of the electric field intensity) radiated from the antenna 20 is large.

As is clear from the experimental results of FIG. 5, the distribution of the microwaves radiated from the antenna 20 may be regulated by changing the stub gap. That is, it is found that the distribution of the microwaves radiated from the antenna 20 may be regulated by controlling the insertion amount of the stub member 51. As a result of further conducting intensive study, the inventors have found that, as the stub gap is small, the regulation range of the distribution of the microwaves radiated from the antenna 20 is large. Further, from the experimental results of FIG. 5, it is found that, when the material of the stub member 51 is a conductor, the regulation range of the distribution of the microwaves radiated from the antenna 20 is large, as compared with the case where the material of the stub member 51 is a dielectric.

In addition, as illustrated in FIG. 1, the plasma processing apparatus 11 further includes a measuring unit 60. The measuring unit 60 measures the density of plasma (hereinafter, referred to as “plasma density”) generated in the processing space S by the microwaves radiated from the antenna 20 along the circumferential direction of the target substrate W. For example, the measuring unit 60 is provided at each of a plurality of positions on the inner circumferential surface of the side wall 22 of the processing container 12 along the circumferential direction of the target substrate W, and measures the plasma density from each of the positions.

When a plurality of processes for plasma-processing the target substrate W in the processing space S are continuously performed, the measuring unit 60 measures the plasma density along the circumferential direction of the target substrate W at a timing when each of the plurality of processes is switched.

Further, as illustrated in FIG. 1, the plasma processing apparatus 11 includes the controller 70 that controls each component of the plasma processing apparatus 11. The controller 70 may be a computer provided with a control device such as, for example, a central processing unit (CPU), a storage device such as, for example, a memory, an input/output device and others. The controller 70 controls each component of the plasma processing apparatus 11 when the CPU operates according to a control program stored in the memory.

For example, the controller 70 measures the plasma density along the circumferential direction of the target substrate W by using the measuring unit 60, and individually controls the insertion amount of each of the plurality of stub members 51 that is used for regulating the distribution of the microwaves, based on the measured plasma density. Hereinafter, examples of a stub insertion amount control process by the controller 70 will be described.

### First Example

First, a first example of the stub insertion amount control process will be described. In the first example, the controller 70 individually controls the insertion amount of each of the plurality of stub members 51 so as to make the distribution of the plasma density become uniform distribution along the circumferential direction of the target substrate W. For example, the controller 70 individually controls the insertion amount of each of the plurality of stub members 51, while monitoring the plasma density measured by the measuring unit 60, until a measurement value of the plasma density is equalized to a predetermined reference value. Further, for example, while monitoring the plasma density measured by the measuring unit 60, the controller 70 calculates an average value of measurement values of the plasma density, and individually controls the insertion amount of each of the plurality of stub members 51 until the measurement values of the plasma density reach the calculated average value.

As described above, according to the first example, since the insertion amount of each of the plurality of stub members 51 is individually controlled so as to make the distribution of the plasma density become uniform distribution along the circumferential direction of the target substrate W, a uniform plasma processing may be performed on the to-be-processed surface of the target substrate W.

### Second Example

Subsequently, a second example of the stub insertion amount control process will be described. In the second example, the controller 70 individually controls the insertion amount of each of the plurality of stub members 51 so as to make the distribution of the plasma density become predetermined ununiform distribution along the circumferential direction of the target substrate W. For example, the controller 70 individually controls the insertion amount of each of the plurality of stub members 51 so as to make the distribution of the plasma density become predetermined distribution obtained by reversing distribution of a film thickness, based on the distribution of the plasma density measured by the measuring unit 60 and the distribution of the film thickness on the target substrate W plasma-processed in the processing space S.

As described above, according to the second example, since the insertion amount of each of the plurality of stub members 51 is individually controlled so as to make the distribution of the plasma density become predetermined ununiform distribution along the circumferential direction of the target substrate W, a desired plasma processing may be performed on the to-be-processed surface of the target substrate W.

Further, according to the second example, since the insertion amount of each of the plurality of stub members 51 is individually controlled so as to make the distribution of the plasma density become predetermined distribution obtained by reversing the distribution of the film thickness, the microwaves from the antenna 20 may be intensively radiated to an area of the to-be-processed surface of the target substrate W where the film thickness is smaller than a predetermined value.

Further, in the first and second examples, the example where the controller 70 continuously controls the insertion amount of each of the plurality of stub members 51 is described. However, the present disclosure is not limited thereto. For example, when a plurality of processes for plasma-processing the target substrate W in the processing space S are continuously performed, the controller 70 may reset the insertion amount of each of the stub members 51 at a timing when each of the plurality of processes is switched.

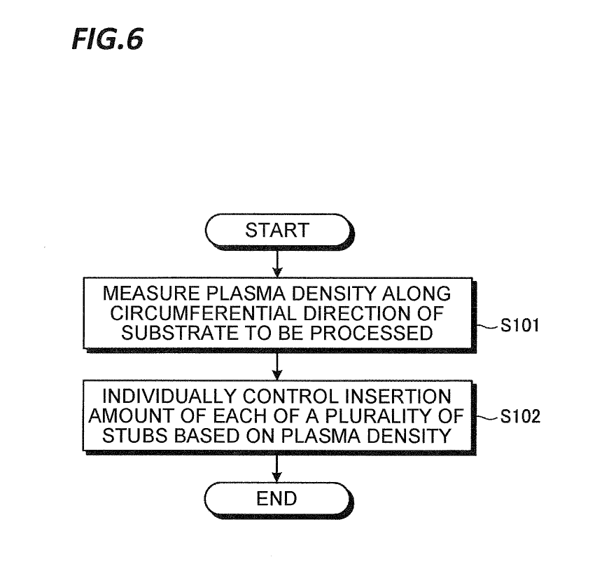

Next, descriptions will be made on an exemplary flow of a plasma processing method using the plasma processing apparatus 11 according to an exemplary embodiment. FIG. 6 is a flow chart illustrating an exemplary flow of the plasma processing method using the plasma processing apparatus according to an exemplary embodiment.

As illustrated in FIG. 6, the controller 70 of the plasma processing apparatus 11 measures the plasma density along the circumferential direction of the target substrate W by using the measuring unit 60 (step S101). Subsequently, based on the measured plasma density, the controller 70 individually controls the insertion amount of each of the plurality of stub members 51 that is used for regulating the distribution of the microwaves (step S102).

As described above, in the plasma processing apparatus 11 according to an exemplary embodiment, the plasma density is measured along the circumferential direction of the target substrate W, and based on the measured plasma density, the insertion amount of each of the plurality of stub members 51 that is used for regulating the distribution of the microwaves is individually controlled. As a result, according to the exemplary embodiment, the distribution of the microwaves may be automatically regulated according to the distribution of the plasma density.

Further, in the above-described exemplary embodiment, descriptions have been made on the example where the plasma processing apparatus 11 individually controls the insertion amount of each of the plurality of stub members 51 that is used for regulating the distribution of the microwaves, based on the plasma density. However, the present disclosure is not limited thereto. For example, the plasma processing apparatus 11 may individually control the insertion amount of each of the plurality of stub members 51 based on a parameter having a correlation with the plasma density, instead of the plasma density. In this case, the measuring unit 60 of the plasma processing apparatus 11 measures the parameter having a correlation with the plasma density, instead of the plasma density. The parameter having a correlation with the plasma density is at least one of a temperature of the side wall 22 of the processing container 12, a temperature of the antenna 20, light emission intensity of the processing space S, and a thickness of an object attached to the side wall 22 of the processing container 12. Then, the controller 70 individually controls the insertion amount of each of the plurality of stub members 51 based on the parameter having a correlation with the plasma density. Accordingly, the distribution of the microwaves may be automatically regulated according to the distribution of the parameter having a correlation of the plasma density.

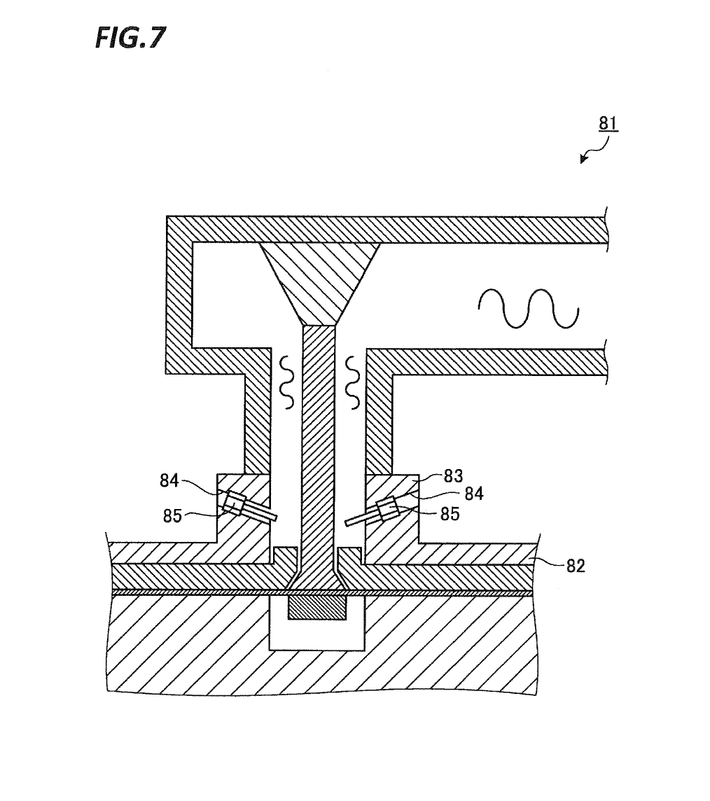

Further, in the above-described exemplary embodiment, the example where the extending direction of the stub members is the horizontal direction, that is, the stub members extend straightly in the radial direction has been described. However, as illustrated in FIG. 7, the extending direction of the stub members may be an obliquely downward direction. FIG. 7 is an enlarged sectional view schematically illustrating the vicinity of the coaxial waveguide of the plasma processing apparatus in this case, and corresponds to FIG. 2. Referring to FIG. 7, on a cooling plate protrusion 83 of a cooling plate 82 provided in a plasma processing apparatus 81 according to another exemplary embodiment, a plurality of screw holes 84 are provided to penetrate a part of the cooling plate protrusion 83 so as to extend obliquely downward when the inner diameter side is regarded as the downward side. Then, stub members 85 are attached to the respective screw holes 84 to extend obliquely downward. With this configuration, the point at which each stub member 85 acts, specifically, the tip end of each stub member 85 may be made approach the slow wave plate 19. In order to suppress the electromagnetic field distribution from being biased in the circumferential direction, it is required that the electromagnetic field distribution be regulated at a position as close as possible to the slow wave plate 19. Accordingly, by providing the stub members 85 to extend obliquely downward, the regulation of the electromagnetic field distribution in the circumferential direction may be more effectively performed.

Further, in the above-described exemplary embodiment, the stub members are supported in the cooling plate protrusion. However, the present disclosure is not limited thereto, and the stub members may be configured to be supported in the outer conductor. Specifically, a screw hole is provided on the outer conductor to penetrate the outer conductor in the radial direction, and a stub member is attached by screw-connecting the screw hole and the screw portion to each other. In this case, the facing portion that faces a part of the outer circumferential surface of the inner conductor becomes a part of the inner circumferential surface of the outer conductor.

Further, in the above-described exemplary embodiment, the stub members are arranged at equal intervals to have the rotational symmetry. However, the stub members may not be arranged at equal intervals as long as the stub members have the rotational symmetry.

Further, in the above-described exemplary embodiment, total six stub members are provided in the circumferential direction. However, the number of the stub members is not limited thereto, and an arbitrary number of stub members, for example, four or eight stub members may be provided according to necessity.

Further, in the above-described exemplary embodiment, the six stub members are provided at one position in the extending direction of the coaxial waveguide, that is, at the same position in the vertical direction. However, the present disclosure is not limited thereto, and the plurality of stub members may be provided at an interval in the extending direction of the coaxial waveguide. When the stub members are provided as an electromagnetic field regulation unit, a part of the microwaves is reflected upward by the above-described rod shaped portion. This may cause a power loss corresponding to reflectivity represented with a value obtained by dividing the electric field intensity of reflected waves by the electric field intensity of incident waves, and as a result of the influence of the reflected waves, the regulation of the electromagnetic field may become complicated, and it may be difficult to make the electromagnetic field distribution uniform. Thus, by providing the plurality of stub members at an interval in the extending direction of the coaxial waveguide, the influence of the reflected waves caused by the stub members may be greatly reduced, and the regulation of the electromagnetic field is facilitated, so that the electromagnetic field distribution may be made uniform in the circumferential direction.

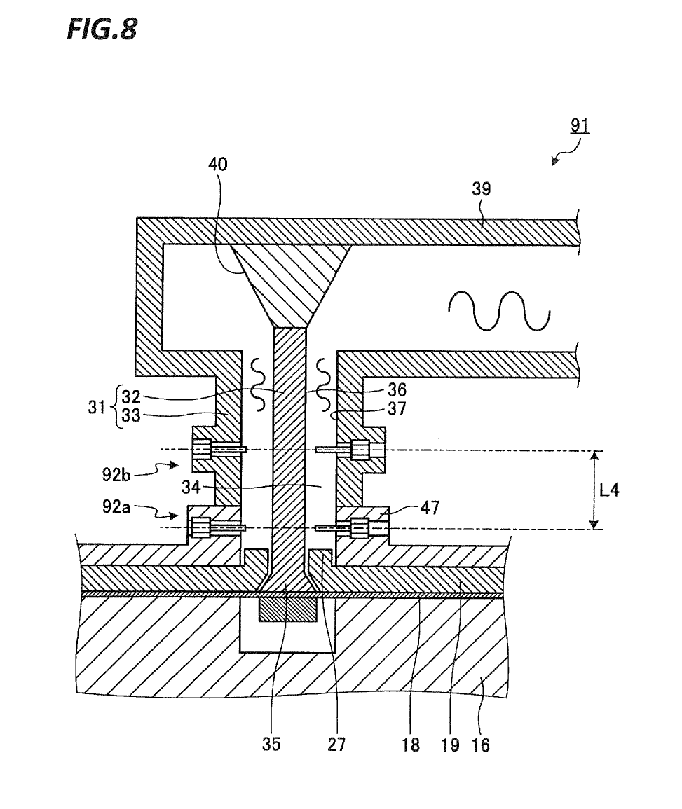

This will be described in detail. FIG. 8 is a sectional view illustrating a part of a plasma processing apparatus in the case described above, and corresponds to FIG. 2. Referring to FIG. 8, in a plasma processing apparatus 91 according to still another exemplary embodiment of the present disclosure, two stub member groups 92a and 92b are provided in the vertical direction in FIG. 8. The first stub member group 92a provided at the lower side as an electromagnetic field regulation mechanism is provided in the cooling plate protrusion 47 of the cooling plate 43, as provided in the plasma processing apparatus 11 illustrated in FIG. 1. Each stub member of the first stub member group 92a has the same configuration as that of each stub member provided in the plasma processing apparatus illustrated in FIG. 1. That is, each stub member provided in the first stub member group 92a is extendable in the radial direction, and is configured to include a screw portion provided to be screw-connected to the screw hole provided in the cooling plate protrusion 47 to extend straightly in the radial direction, and a rod shaped portion. Meanwhile, the second stub member group 92b provided at the upper side as a reflected wave compensation mechanism is provided in the outer conductor 33 of the coaxial waveguide 31. Each stub member provided in the second stub member group 92b also has the same configuration as that of each stub member provided in the first stub member group 92a. The stub member is extendable in the radial direction and is configured to include a screw portion provided to be screw-connected to a screw hole provided in the outer conductor 33 to extend straightly in the radial direction, and a rod shaped portion.

In the first stub member group 92a of the two stub member groups, six stub members are substantially equally arranged in the circumferential direction as in the case illustrated in FIG. 1. In the second stub member group 92b as well, six stub members are substantially equally arranged in the circumferential direction. In addition, the two stub member groups mentioned herein indicate that stub member groups each including the six stub members provided at intervals in the circumferential direction are provided at an interval in the vertical direction.

As for the circumferential position where each stub member of the first and second stub member groups 92a and 92b is provided, each stub member of the first stub member group 92a and each stub member of the second stub member group 92b are provided at the same position. That is, when viewed from the upper side in FIG. 8, the stub members appear as illustrated in FIG. 4, and each stub member of the first stub member group 92a and each stub member of the second stub member group 92b appear to overlap with each other. In addition, the interval in the vertical direction between the first stub member group 92a and the second stub member group 92b, that is, the distance L4 between the first stub member group 92a and the second stub member group 92b is ¼ of the in-waveguide wavelength of the coaxial waveguide 31. The distance L4 between the first stub member group 92a and the second stub member group 92b is the distance between the axial direction of the first stub member group 92a indicated by an alternate long and short dashed line in FIG. 8, that is, the central position of the first stub member group 92a in the vertical direction and the central position of the second stub member group 92b in the vertical direction. Further, the microwave reflectivity of each stub member provided in the first stub member group 92a and the microwave reflectivity of each stub member provided in the second stub member group 92b are the same. A material of each stub member provided in the first and second stub member groups 92a and 92b is, for example, alumina or metal.

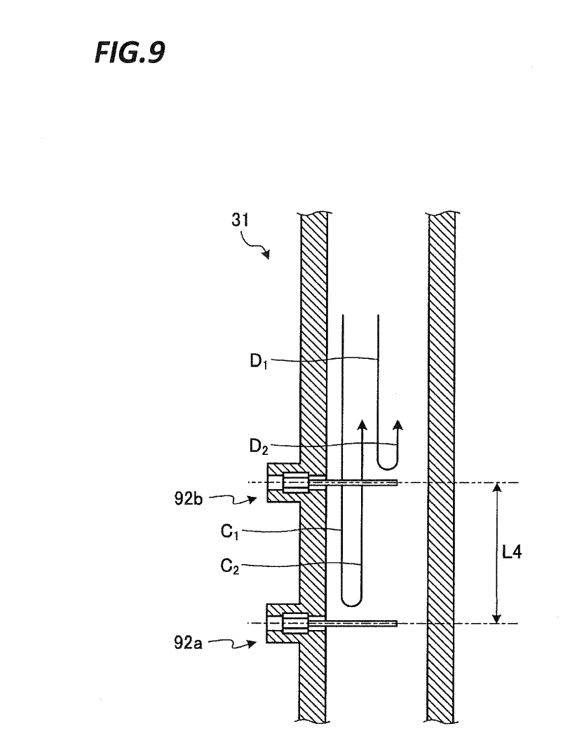

With this configuration, the electromagnetic field distribution may be more effectively made uniform by the first stub member group 92a functioning as an electromagnetic field regulation mechanism and the second stub member group 92b functioning as a reflected wave compensation mechanism. In addition, in FIGS. 8 and 9, the same configurations as those of the plasma processing apparatus 11 illustrated in FIGS. 1 and 2 will be denoted by the same reference numerals as used in FIGS. 1 and 2, and descriptions thereof will be omitted.

Here, the principle of the plasma processing apparatus 91 illustrated in FIG. 8 will be described. FIG. 9 is an enlarged sectional view schematically illustrating the vicinity of the coaxial waveguide 31 provided in the plasma processing apparatus 91 illustrated in FIG. 8. From the viewpoint of facilitating the understanding, FIG. 9 schematically illustrates, for example, the configuration of the first and second stub member groups 92a and 92b.

Referring to FIGS. 8 and 9, an incident wave C1 that is incident downward from the upper side reaches a stub member provided in the first stub member group 92a as an electromagnetic field regulation mechanism, and then, a part of the incident wave C1 is reflected upward as a reflected wave C2. Further, an incident wave D1 reaches a stub member provided in the second stub member group 92b as a reflected wave compensating mechanism, and then, a part thereof is reflected upward as a reflected wave D2. Here, the reflected wave C2 that has been delayed in time by the reciprocating length of the distance L4 between the first stub member group 92a and the second stub member group 92b interferes with the reflected wave D2. In this case, since the distance L4 between the first stub member group 92a and the second stub member group 92b is ¼ of the in-waveguide wavelength of the coaxial waveguide 31, the reciprocating length of the distance between the first stub member group 92a and the second stub member group 92b becomes ½ of the in-waveguide wavelength of the coaxial waveguide 31. Then, the phases of the respective reflected waves C2 and D2 are deviated from each other by 180 degrees. Here, since the reflectivity of the stub member provided in the first stub member group 92a and the reflectivity of the stub member provided in the second stub member group 92b are the same, the reflected waves C2 and D2 are thoroughly set off so that the electromagnetic field regulation in which the influence of the reflected waves is greatly reduced may be implemented. Accordingly, the electromagnetic field may be more effectively and uniformly supplied.

Here, the reflectivity of the stub member provided in the first stub member group 92a and the reflectivity of the stub member provided in the second stub member group 92b are set to be the same. However, according to a specific exemplary embodiment, each reflectivity may be set to 0.1 to 0.2, and the total of the reflectivities may be set to 0.03 or less. However, strictly speaking, the incident wave C1 is partially reflected by the stub member provided in the second stub member group 92b and becomes small. Thus, in consideration of this influence, the reflectivity of the stub member provided in the first stub member group 92a and the reflectivity of the stub member provided in the second stub member group 92b may be mutually exchanged.

Further, in the exemplary embodiment illustrated in FIG. 8, the interval in the vertical direction between the first stub member group and the second stub member group is set to ¼ of the in-waveguide wavelength of the coaxial waveguide. However, the present disclosure is not limited thereto, and the interval may be odd number times ¼ of the in-waveguide wavelength of the coaxial waveguide. Accordingly, the phases of the respective reflected waves may be made deviated from each other by 180 degrees, and thus, the above-described effect may be achieved. Further, the influence of the reflected wave may be reduced even when the interval is somewhat deviated from the odd number times ¼ of the in-guide wavelength of the coaxial waveguide.

In the above-described exemplary embodiment illustrated in FIG. 8, the circumferential position of each stub member provided in the first stub member group and the circumferential position of each stub member provided in the second stub member group are set to be the same. However, the present disclosure is not limited thereto, and the positions may be slightly deviated from each other in the circumferential direction. Further, the number of the stub members provided in the first stub member group and the number of the stub members provided in the second stub member group may be different from each other.

In addition, in the above-described exemplary embodiment illustrated in FIG. 8, each stub member provided in the first and second stub member groups is provided to extend straightly in the radial direction. However, the present disclosure is not limited thereto, and the extending direction of each stub member may be the obliquely downward direction. In this case, the extending direction of each stub member provided in one of the first and second stub member groups may be the obliquely downward direction, or the extending direction of each stub member provided in both the first and second stub member groups may be the obliquely downward direction.

In addition, in the above-described exemplary embodiment, the stub member is used as a changing unit. However, the present disclosure is not limited thereto, and the changing unit may have another configuration. That is, for example, a protrusion may be provided on the inner circumferential surface of the outer conductor to extend in the radial direction and regulate the extending distance, and this protrusion may be used as the changing unit. Alternatively, the changing unit may be configured such that, by recessing the outer diameter surface of the outer conductor, the distance between the inner circumferential surface of the outer conductor and the outer circumferential surface of the inner conductor is changed according to the recess.

In addition, in the above-described exemplary embodiment, the changing unit is provided at the side of the outer conductor. However, the present disclosure is not limited thereto, and the changing unit may be provided at the side of the inner conductor. Specifically, the changing unit may be configured to extend from the outer circumferential surface of the inner conductor toward the outer diameter side, that is, toward the direction in which the gap is formed, and regulate the extending distance.

Although the exemplary embodiments of the present disclosure have been described, the present disclosure is not limited thereto. Various modifications or changes may be made to the illustrated exemplary embodiments within the scope identical or equivalent to that of the present disclosure.

### DESCRIPTION OF SYMBOL

11, 81, 91: plasma processing apparatus
12: processing container
13: gas supply unit
14: holding table
15: microwave generator
16: dielectric plate
17: slot holes
18: slot antenna plate
19: slow wave plate
20: antenna
21: bottom portion
22: side wall
23: exhaust hole
24: O-ring
25: surface
26a: inner circumferential side slot hole group
26b: outer circumferential side slot hole group
27: slow wave protrusion
28: center
31: coaxial waveguide
32: inner conductor
33: outer conductor
34: gap
35, 38: end
36: outer circumferential surface
37, 50: inner circumferential surface
39: waveguide
40: mode converter
41: dielectric plate pressing ring
42: antenna press
43, 82: cooling plate
44: electromagnetic shielding elastic member
45: outer periphery fixing ring
46: center fixing plate
47, 83: cooling plate protrusion
48: slow wave plate positioning unit
49: accommodating recess
51, 85: stub member
52: rod shaped portion
53: screw portion
54, 84: screw hole
60: measuring unit
70: controller
92a: first stub member group
92b: second stub member group

1. A plasma processing apparatus comprising:
a processing container that defines a plasma processing space;
a holder that is provided inside the processing container to hold a substrate to be processed;
a gas supply unit that supplies gas into the plasma processing space;
an antenna that radiates microwaves for generating plasma of the gas supplied into the plasma processing space, to the plasma processing space;
a coaxial waveguide that supplies the microwaves to the antenna;
a plurality of stubs that are inserted into the coaxial waveguide and regulate distribution of the microwaves radiated from the antenna according to an insertion amount;
a measuring unit that measures density of the plasma generated in the plasma processing space by the microwaves radiated from the antenna or a parameter having a correlation with the density of the plasma along a circumferential direction of the substrate to be processed; and
a controller that individually controls an insertion amount of each of the plurality of stubs used for regulating the distribution of the microwaves, based on the density of the plasma or the parameter.

2. The plasma processing apparatus of claim 1, wherein the controller individually controls the insertion amount of each of the plurality of stubs so as to make the distribution of the density of the plasma or the distribution of the parameter become uniform distribution along the circumferential direction of the substrate to be processed.

3. The plasma processing apparatus of claim 1, wherein the controller individually controls the insertion amount of each of the plurality of stubs so as to make the distribution of the density of the plasma or the distribution of the parameter become predetermined ununiform distribution along the circumferential direction of the substrate to be processed.

4. The plasma processing apparatus of claim 3, wherein the controller individually controls the insertion amount of each of the plurality of stubs so as to make the distribution of the density of the plasma or the distribution of the parameter become predetermined distribution obtained by reversing distribution of a film thickness, based on the distribution of the density of the plasma or the distribution of the parameter, and distribution of a film thickness on the substrate plasma-processed in the plasma processing space.

5. The plasma processing apparatus of claim 1, wherein the parameter is at least one of a temperature of a side wall of the processing container, a temperature of the antenna, light emission intensity of the plasma processing space, and an object attached to the side wall of the processing container.

6. The plasma processing apparatus of claim 1, wherein when a plurality of processes for plasma-processing the substrate to be processed in the plasma processing space are continuously performed, the measuring unit measures the density of the plasma or the parameter along the circumferential direction of the substrate to be processed at a timing when each of the plurality of processes is switched.

7. The plasma processing apparatus of claim 1, wherein the coaxial waveguide includes an inner conductor and an outer conductor provided outside the inner conductor while having a gap from the inner conductor,
the stubs are inserted into the gap, and
a material of a portion inserted into the gap is a dielectric or a conductor.

8. A plasma processing method in a plasma processing apparatus which comprises: a processing container that defines a plasma processing space;
a holder that is provided inside the processing container to hold a substrate to be processed;
a gas supply unit that supplies gas into the plasma processing space;
an antenna that radiates microwaves for generating plasma of the gas supplied into the plasma processing space, to the plasma processing space;
a coaxial waveguide that supplies the microwaves to the antenna;
a plurality of stubs that are inserted into the coaxial waveguide and regulate distribution of the microwaves radiated from the antenna according to an insertion amount;
a measuring unit that measures density of the plasma generated in the plasma processing space by the microwaves radiated from the antenna or a parameter having a correlation with the density of the plasma along a circumferential direction of the substrate to be processed; and
a controller that individually controls an insertion amount of each of the plurality of stubs used for regulating the distribution of the microwaves, based on the density of the plasma or the parameter, the plasma processing method comprising:
measuring density of plasma generated in the plasma processing space by the microwaves radiated from the antenna or a parameter having a correlation with the density of the plasma along a circumferential direction of the substrate to be processed; and
individually controlling an insertion amount of each of the plurality of stubs used for regulating the distribution of the microwaves, based on the density of the plasma or the parameter.
